(19) United States
(12) Patent Application Publication
(10) Pub. No.: US 2025/0307479 A1
(43) Pub. Date: Oct. 2, 2025

(54) TECHNIQUES FOR PHYSICS AWARE SMART MESHING

(71) Applicant: ANSYS, INC., CANONSBURG, PA (US)

(72) Inventors: Mehdi ABARHAM, Belmont, CA (US); Jerry LIM, Canonsburg, PA (US); Saeed ASGARI, Westborough, MA (US)

(21) Appl. No.: 18/654,611

(22) Filed: May 3, 2024

Related U.S. Application Data
(60) Provisional application No. 63/570,063, filed on Mar. 26, 2024.

(51) Int. Cl. G06F 30/10

(52) U.S. Cl. CPC G06F 30/10

(57) ABSTRACT

Computer-implemented devices, systems, and methods for physics-aware smart meshing are described. In various embodiments, physical aware smart meshing may include, or refer to, the generation of a dynamically sized mesh for a computer model based on one or more estimated physical fields corresponding to the computer model. The disclosed analysis techniques can include a series of steps including, for example, decomposing models, determining block properties, scaling from an original domain to a scaled domain, estimating physical fields, scaling from the scaled domain to the original domain, superpositioning of physical fields, and generating dynamically sized meshes. In various embodiments, the dynamically sized mesh is generated in an efficient and accurate manner without needing solve/adapt iterations.

### CROSS-REFERENCE TO RELATED APPLICATIONS

This application claims the benefit of and priority to U.S. Provisional Patent Application No. 63/570,063, filed Mar. 26, 2024, and titled “Techniques for Physics Aware Smart Meshing”. This application is incorporated herein by reference in its entirety.

### FIELD OF DISCLOSURE

This disclosure relates generally to computer-based modeling and more particularly to physics aware smart meshing.

### BACKGROUND

In computing, a mesh may refer to a subdivision of a continuous geometric space into discrete geometric and topological cells. Meshes are used for rendering to a computer screen and for physical simulation such as finite element analysis or computational fluid dynamics. Meshes are usually composed of cells having simple shapes (e.g., triangles or rectangles) in order to simplify calculations. For example, it is much simpler to perform operations, such as finite element calculations, on simple shapes than performing the operations directly on complicated spaces and shapes, such as a bridge. Thus, the strength of the bridge can be simulated by performing calculations on each triangle and calculating the interactions between triangles.

Meshes can be created by computer algorithms, often with human guidance through a GUI, depending on the complexity of the domain and the type of mesh desired. A typical goal is to create a mesh that accurately captures the input domain geometry, with high-quality cells, and without so many cells as to make subsequent calculations impractical. This consideration is also balanced with the need for meshes to be fine (have small elements) in areas that are important for the subsequent calculations.

### SUMMARY

The disclosure describes computer-implemented devices, systems, and methods for physics-aware smart meshing. In various embodiments, physical aware smart meshing may include, or refer to, the generation of a dynamically sized mesh for a computer model based on one or more estimated physical fields corresponding to the computer model. The disclosed analysis techniques can include a series of steps including, for example, decomposing models, determining block properties, scaling from an original domain to a scaled domain, estimating physical fields, scaling from the scaled domain to the original domain, superpositioning of physical fields, and generating dynamically sized meshes. In various embodiments, the dynamically sized mesh is generated in an efficient and accurate manner without needing solve/adapt iterations.

According to one aspect of the present disclosure, embodiments may include a method comprising A computer-implemented method, comprising: receiving, by a memory of a system, a model of an object in an original domain with a set of boundary conditions; decomposing, by one or more processors of the system, the model of the object as a set of blocks; determining, by the one or more processors of the system, non-dimensional numbers for each block based on the set of boundary conditions; identifying a scaled model for each block based on the non-dimensional numbers and the boundary conditions, wherein properties for each block are scaled from the original domain to fit the scaled model corresponding to the block in a scaled domain; determining, by the one or more processors of the system, an estimated scaled field of a physical quantity for each block in the set of blocks based on the scaled properties for each block in the set of blocks and the corresponding scaled model; generating an estimated actual field of the physical quantity for each block in the set of blocks by re-scaling the estimated scaled field for each block from the scaled domain to the original domain; and generating, by the one or more processors of the system, a dynamically sized mesh for computational analysis of the model based on the estimated actual field of the physical quantity for each block in the set of blocks.

In some embodiments, the non-dimensional numbers comprise at least one of a Reynolds number and a Rayleigh number. In various embodiments, determining, by the one or more processors of the system, the estimated scaled field of the physical quantity for each block in the set of blocks based on the set of scaled properties for each block in the set of blocks comprises performing a multi-variable linear regression or a multi-level interpolation using a trained model database of stored solutions of fields of the physical quantity for the scaled model in the scaled domain. In various such embodiments, wherein the trained model database of stored solutions is generated based on solutions to simulations performed on the scaled model. Many embodiments may include superpositioning the estimated actual field of the physical quantity for each block in the set of blocks onto the model; and summing overlapping estimated actual fields to determine the estimated actual field of the physical quantity for the object. Many such embodiments may include calculating a set of gradient values based on the estimated final field of the physical quantity for the object and estimated fields for the set of blocks; and generating, by the one or more processors of the system, the dynamically sized mesh for computational analysis of the model based on the set of gradient values. Some such embodiments may include summing overlapping estimated actual fields and adding an ambient value of the physical quantity to determine the final estimated field of the physical quantity for the object. In some such embodiments, the physical quantity comprises temperature and the ambient value comprises an ambient temperature. In various embodiments, each block in the set of blocks has a minimum aspect ratio of 0.8. In many embodiments, the scaled model is a rectangular block.

Any of the above methods can be embodied on a non-transitory computer-readable medium programmed with executable instructions that, when executed, perform the method. Further, an apparatus or system can be programmed with executable instructions that, when executed by a processing system that includes at least one hardware processor, can perform any of the above methods.

The subject matter described hereby provides many technical advantages. As described in more detail below, the computer-based techniques of the current disclosure improve the functioning of a computer system as compared to conventional approaches because the techniques described herein support generation of dynamically sized meshes that are more accurate, more efficient (e.g., faster, smaller memory requirements, etcetera), and/or have a reduced processing burden versus conventional approaches.

### BRIEF DESCRIPTION OF THE DRAWINGS

The current disclosure is illustrated by way of example and not limitation in the figures of the accompanying drawings in which like references indicate similar elements. To easily identify the discussion of any particular element or act, the most significant digit or digits in a reference number refer to the figure number in which that element is first introduced.

FIG. 1A illustrates a logic flow which can be used according to one or more embodiments described hereby to utilize smart meshing according to some embodiments.

FIG. 1B illustrates an exemplary system for implementing one or more embodiments described hereby.

FIG. 2 illustrates a process flow for a smart meshing platform according to some embodiments.

FIG. 3 illustrates a block diagram of an exemplary smart meshing platform according to some embodiments.

FIG. 4 illustrates a process flow of a training procedure for estimation of physical fields according to some embodiments.

FIGS. 5A and 5B illustrate various aspects of a natural convection simulation utilized in a training procedure according to some embodiments.

FIGS. 6A and 6B illustrate various aspects of a forced convection simulation utilized in a training procedure according to some embodiments.

FIG. 7 illustrates a process flow for generating a dynamically sized mesh according to some embodiments.

FIGS. 8A-8E illustrate various aspects of generating a dynamically sized mesh for a model of a light bulb according to some embodiments.

FIGS. 9A-9C illustrate exemplary dynamically sized meshes generated based on different configurations according to some embodiments.

FIGS. 10A-10C illustrate various aspects of superpositioning according to some embodiments.

FIGS. 11A-11E illustrate various aspects of generating a dynamically sized mesh for a model of a printed circuit board and integrated circuit components according to some embodiments.

FIGS. 12A-12D illustrate various aspects of generating a dynamically sized mesh for a model of an electronics enclosure box according to some embodiments.

FIG. 13 illustrates a logic flow according to some embodiments.

FIG. 14 illustrates an exemplary system which may be used in conjunction with one or more embodiments described hereby.

FIGS. 15A-15C illustrate exemplary system which may be used in conjunction with one or more embodiments described hereby.

### DETAILED DESCRIPTION

Various embodiments and aspects will be described with reference to details discussed below, and the accompanying drawings will illustrate the various embodiments. The following description and drawings are illustrative and are not to be construed as limiting. Numerous specific details are described to provide a through understanding of various embodiments. However, in certain instances, well-known or conventional details are not described in order to provide a concise discussion of embodiments.

Reference in the specification to “one embodiment” or “an embodiment” means that a particular feature, structure, or characteristic described in conjunction with the embodiment can be included in at least one embodiment. The appearances of the phrase “in one embodiment” in various places in the specification do not necessarily refer to the same embodiment. The processes depicted in the figures that follow are performed by processing logic that comprises hardware (e.g., circuitry, dedicated logic, etcetera), software, or a combination of both. Although the processes are described below in terms of some sequential operations, it should be appreciated that some of the operations described may be performed in a different order. Moreover, some operations may be performed in parallel rather than sequentially.

Embodiments disclosed hereby provide techniques for physics-aware smart meshing. In various embodiments, physics-aware smart meshing may include, or refer to, the generation of a dynamically sized mesh for a computer model based on one or more estimated physical fields corresponding to the computer model. These meshes can be used for computer-based physical simulations. Further, a dynamically sized mesh is composed of cells of different sizes that are determined based on accuracy needed. In other words, areas of the mesh that need high accuracy have smaller cell sizes than areas of the mesh that need lower accuracy.

Existing techniques for mesh generation may utilize a uniform cell size in the mesh. However, this technique cannot provide accurate results without excessive resource demands. For example, cells need to be finer in areas with fast changing physical fields, but can be larger in areas with slow changing or unchanging physical fields. However, when all the cells have a uniform size, either accuracy or computational efficiency must be sacrificed. Other existing techniques, such as adaptive meshing, can generate dynamically sized meshes, but they still require excessive compute resources. For example, adaptive meshing requires an existing solution and frequent refinement updates during the solver stage. Adaptive meshing may start with a coarse mesh having sufficient mesh resolution. A solution for a given problem setup is then determined and the coarse mesh is adapted based on appropriate adaption criterion. Next, new boundary nodes are projected to the geometry and the solve/adapt steps are repeated until convergence between solve/adapt iterations. However, the solve/adapt iterations require unnecessary and excessive compute resources to perform.

Accordingly, embodiments disclosed hereby provide techniques for physics-aware smart meshing in an efficient and accurate manner. For example, the disclosed techniques provide a physics-aware approach to predict an efficient reduced order solution to guide mesh generation. In another example, the disclosed techniques leverage symmetry (e.g., in geometry) and linearity (e.g., in physics) to significantly reduce redundancy (e.g., via superpositioning), such as for generating training data and/or estimated physical fields, thereby improving overall computational resource requirements. In yet another example, non-dimensional approaches (e.g., via Buckingham π theorem) and high order regression interpolation techniques are utilized to effectively address scalability requirements, such as for generating training data and/or estimated physical fields. Accordingly, the current disclosure provide a fast and accurate method for meshing with superior scalability compared to conventional approaches. These and other techniques of the current disclosure can be utilized to eliminate the solve/adapt iterations required for adaptive meshing. For example, a trained machine learning model can provide the adaption function used to generate a mesh with an efficient and accurate size distribution. In various embodiments, the disclosed techniques can include a series of steps including, for example, decomposing models, determining block properties, scaling from an original domain to a scaled domain, estimating physical fields, scaling from the scaled domain to the original domain, superpositioning of physical fields, and generating dynamically sized meshes. In various embodiments, the size of cells in a mesh can be optimized with these techniques to balance computational efficiency with the need for accuracy, such as in areas of changing physical field (e.g., large gradients).

Therefore, the subject matter described hereby provides many technical advantages. For example, as described above and in more detail below, the computer-based techniques of the current disclosure improve the functioning of a computer system as compared to conventional approaches, such as by supporting generation of dynamically sized meshes that are more accurate, more efficient (e.g., faster, smaller memory requirements, etcetera), and/or have a reduced processing burden versus conventional approaches. In these and other ways, components/techniques described hereby may provide many technical advantages. For example, the computer-based techniques of the current disclosure improve the functioning of computer-based modeling as compared to conventional approaches because the techniques enable generic solution guided meshing that is not limited to any particular application, program, geometry, or physics. In another example, the computer-based techniques utilize scaling and multi-level interpolation to determine estimated solutions (e.g., estimated physical fields). In yet another example, the computer-based techniques provide reduced ordering modeling techniques that consider all input parameters. In yet another example, the computer-based techniques provide machine learning based solutions (e.g., deep learning, multi-variable linear and polynomial regressions) for estimated solutions. Accordingly, embodiments disclosed hereby can be practically utilized to improve the functioning of a computer and/or to improve a variety of technical fields including computer-based modeling, meshing, physical simulation (e.g., finite element analysis and computational fluid dynamics), and machine learning.

The above summary does not include an exhaustive list of all embodiments in this disclosure. All systems and methods can be practiced from all suitable combinations of the various aspects and embodiments summarized above, and also those disclosed in the Detailed Description below.

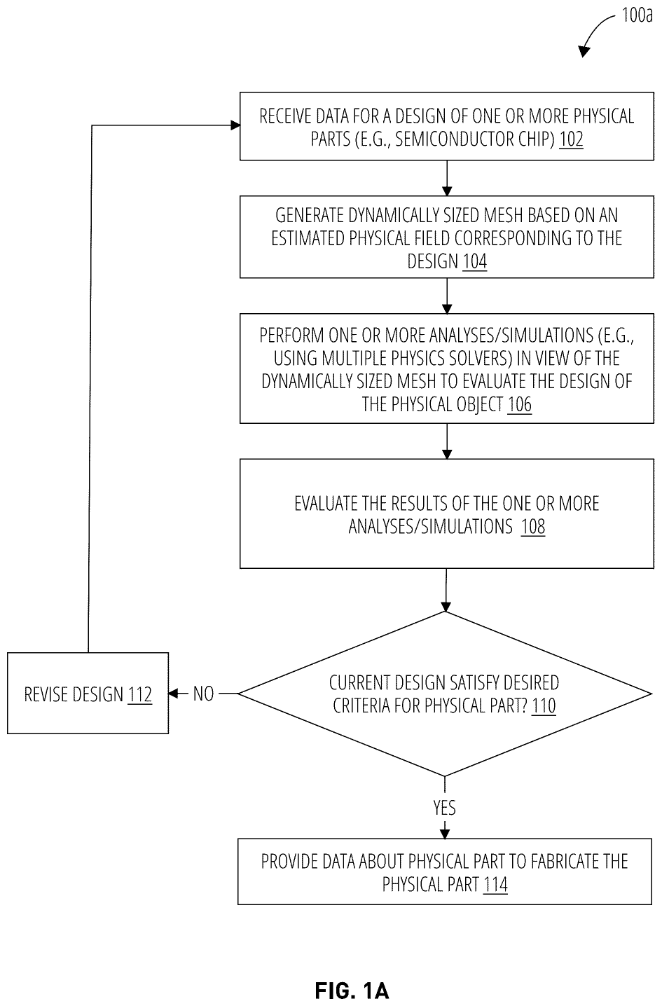

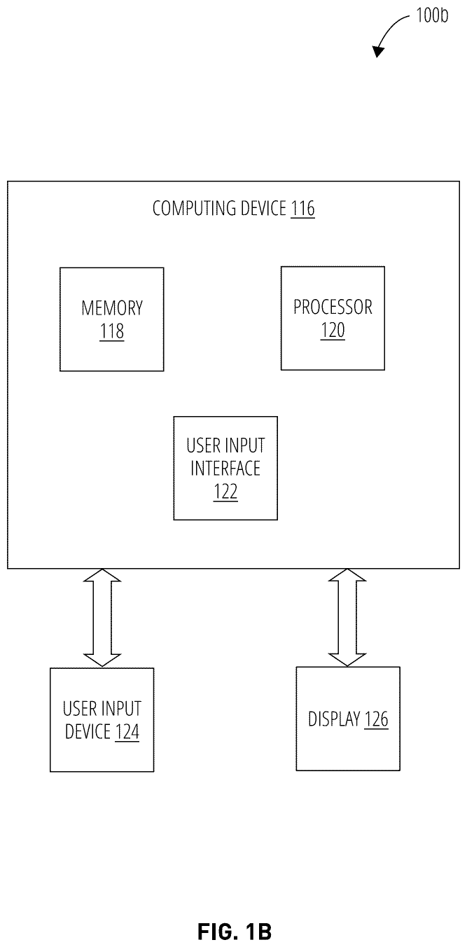

FIG. 1A shows a method in which these design requirements can be tested relative to a particular design of a system or object which is being simulated. At block 102, a data processing system (e.g., a computer executing simulation software to provide a simulation system) can receive data about a design for a system or object. The data can be created in CAD software on a data processing system, and the data can include information regarding various characteristics and properties of a design and/or device. For example, geometry information (e.g., sizes and shapes) about the system or object, component information, and material information about the material(s) that will be used to manufacture the system or object may be provided to the simulation system.

At block 104, a dynamically sized mesh may be generated based on an estimated physical field corresponding to the design. Generation of the dynamically sized mesh is discussed in more detail below. Then at block 106, the data processing system can perform one or more analyses including one or more simulations to evaluate the design of the object (e.g., chip) or system (e.g., collection of parts) in view of the dynamically sized mesh. The simulations may include one or more physics simulations or multiphysics simulations (such as simulations using different physics solvers over different spaces in the simulations). These analyses and simulations can provide results or solution data that can use, or be used in, aspects and embodiments described hereby. It will be appreciated that these simulations are not equivalent to the simulations described in the training procedure for estimation of physical fields and, instead, relate to determining a full solution (e.g., full solution 800e), such as during a solver stage.

At block 108, the data processing system and/or designer can evaluate the results of one or more analyses/simulations to determine whether the design of the system or object satisfies certain desired criteria for the design. This determination is shown at decision block 110. If the one or more criteria are satisfied, then the data processing system and/or designer at block 114 can provide data about the system or object (including build parameters) to allow the fabrication or manufacture of the system or object. For example, if the one or more criteria are satisfied, a CAD file can be produced that described how to build the system or object, and the system or object can be manufactured based on that CAD file. If the criteria are not satisfied as determined at decision block 110, the data processing system and/or designer can revise the design at block 112 (for example, by changing sizes, spacing, materials, and/or manufacturing parameters used in the system or object, etcetera) and repeat the process by performing additional further analyses and/or simulations to evaluate the redesigned system or object. This can be repeated until the desired criteria are achieved for the system of object.

FIG. 1B illustrates a system 100b that can implement one or more techniques disclosed hereby, such as performing various analyses and removing a powder representation from an initial model to produce an updated model. The system 100b can include a computing device 116. The computing device 116 can include memory 118 for storing instructions for execution by one or more data processor/processor cores 120. The computing device 116 can also include a user input interface 122 that can receive instructions provided by a user input device 124 and/or via a graphical user interface. The system 100b can optionally include a display 126 that can render visual information that corresponds to simulation and/or analysis results.

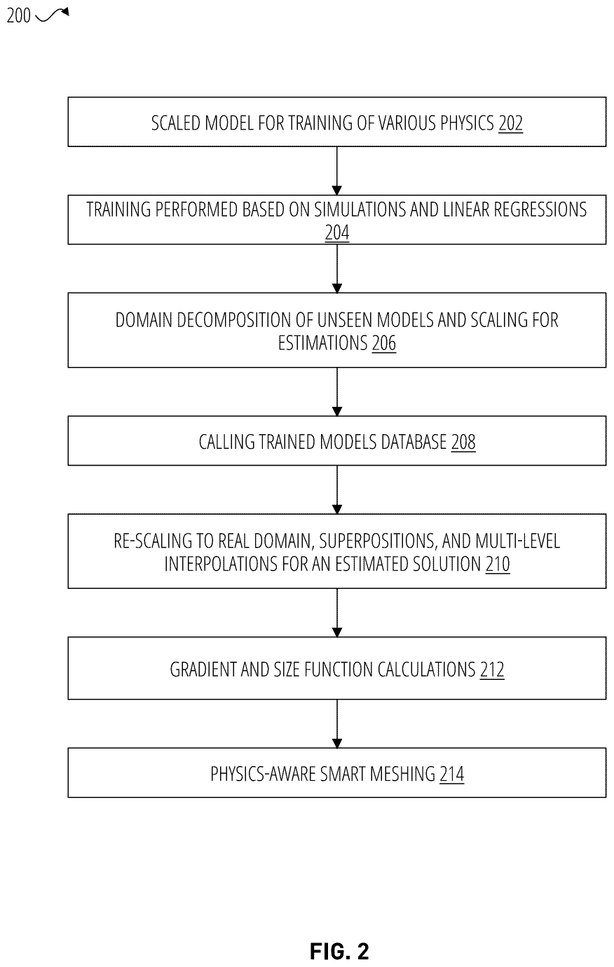

FIG. 2 illustrates a process flow 200 for a smart meshing platform according to some embodiments. The process flow 200 is performed by processing logic that may comprise hardware (circuitry, dedicated logic, etc.), software (such as is run on a general purpose computer system or a dedicated machine), firmware, or a combination. It will be appreciated that process flow 200 provides a high level description of various techniques disclosed hereby and additional details regarding the techniques are described in more detail with respect to other figures below. In various embodiments, the process flow 200 is performed by one or more of one or more components of computing device 116, smart meshing platform 302, computer-implemented environment 1400, system 1500a, system 1500b, and/or standalone computer architecture 1500c. Embodiments are not limited in this context.

Referring to FIG. 2, the process flow 200 begins at block 202. At block 202, a scaled model for training of various physics is determined. For example, scaled models may be determined and configured for simulating various types of physical effects relevant to a design (e.g., electromagnetism, thermodynamics, acoustics, mechanics, optics, etc.). Proceeding to block 204, training is performed based on simulations and linear regressions. For example, various simulations may be performed on the scaled model to generate training data. In some such examples, a machine learning model may be trained based on simulation results for each non-dimensional number (e.g., Reynolds or Rayleigh numbers) to output a corresponding estimated physical fields based on non-dimensional numbers provided as input. The variable of interest may be stored on a fixed mesh for each scenario and a spatial database of solutions may be stored for each case. Accordingly, a database of trained models for each non-dimensional number may be generated, linear regression to interpolate between cases and build a unified model for prediction in unseen scenarios. In various embodiments, block 202 and block 204 may correspond to a training procedure and blocks 206-214 may correspond to a production procedure (i.e., generation of estimated physical fields for an unseen model).

At block 206, domain decomposition and scaling of unseen models for field estimation is performed. For example, an unseen models may be decomposed into a set of blocks and the set of blocks is scaled from the original domain (also referred to as model domain or real domain) of the unseen model to a scaled domain of the scaled model. In various embodiments, the Buckingham x theorem in conjunction with scaling of physics for each setup is utilized to consolidate all the training configurations into one single sized model (i.e., the scaled model). For example, for a physically meaningful equation involving a certain number, n, of physical variable, then the original equitation can be rewritten in terms of a set of p=n−k dimensionless parameters, where k is the number of physical dimensions involved. This can be utilized in a method of computing sets of dimensionless parameters from given variable, or nondimensionalization, even when the form of the equation is unknown.

Continuing to block 208, the trained models database may be called. For example, an estimated solution for one or more variables of interest (e.g., temperature) may be calculated for each block in the set of blocks using the trained model database of stored solutions. In some embodiments, this may be done by multi-variable linear regression techniques or multi-level interpolations. Proceeding to block 210, an estimated actual solution (e.g., estimated actual field) is determined by rescaling to the original domain, performing superpositioning, and multi-level interpolations. At block 212, gradient and size function calculations may be performed. For example, for each variable of interest, gradients may be calculated based on the estimated actual solution. Size functions are then calculated for meshing based on the gradients. Next, at block 214, physics-aware smart meshing is performed. In many embodiments, performance of the meshing is guided using the size function.

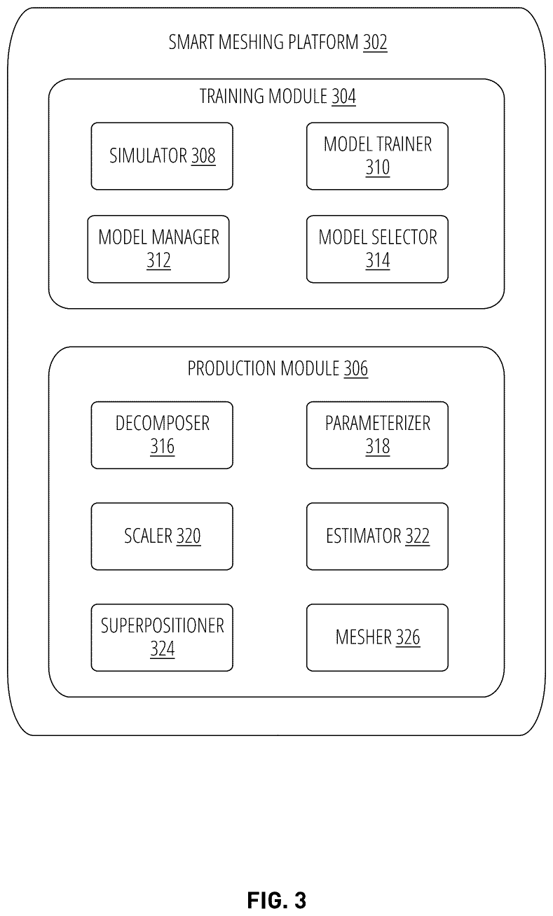

FIG. 3 illustrates a block diagram of an exemplary smart meshing platform 302 according to some embodiments. In various embodiments, the smart meshing platform 302 may be implemented in processing circuitry to perform various aspects of generating, or supporting generation of, a dynamically sized mesh. In many embodiments, smart meshing platform 302, or one or more components thereof, may perform one or more logic flows and/or techniques disclosed hereby. In the illustrated embodiment, smart meshing platform 302 includes a training module 304 and a production module 306. Accordingly, training module 304 may perform one or more aspects of training procedures described hereby and production module 306 may perform one or more aspects of production procedures described hereby. It will be appreciated that one or more components of FIG. 3 may be the same or similar to one or more other components disclosed hereby. Further, aspects discussed with respect to various components in FIG. 3 may be implemented by one or more other components from one or more other embodiments without departing from the scope of this disclosure. For example, smart meshing platform 302, or one or more components thereof, may be implemented by one or more components of computing device 114, computer-implemented environment 1400, system 1500a, system 1500b, and/or standalone computer architecture 1500c without departing from the scope of this disclosure. Further, one or more components of smart meshing platform 302 may be implemented by different computing components without departing from the scope of this disclosure. For example, training module 304 and production module 306 may be implemented by different computing systems. Embodiments are not limited in this context.

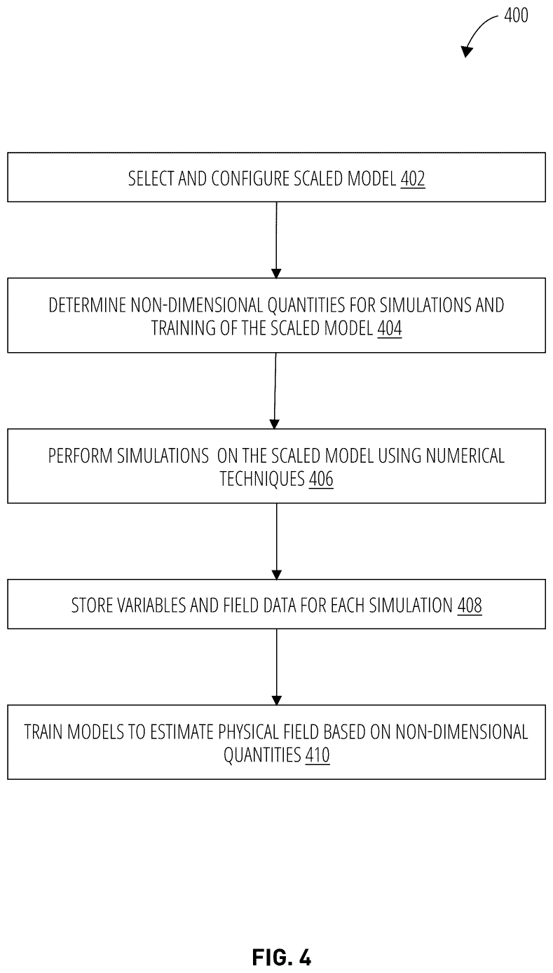

The training module 304 includes a simulator 308 and a model trainer 310. As described in more detail below, training module 304 may implement process flow 400 of FIG. 4 to perform a training procedure for estimation of physical fields. In various embodiments, the simulator 308 may perform one or more simulations on a scaled model. In several embodiments, the model trainer 310 may train one or more machine learning models based on results generated by simulator 308. In several such embodiments, model trainer 310 may utilize linear regression to interpolate between cases and build a unified model for prediction in unseen scenarios. In many embodiments, the model manager 312 may generate and maintain a trained model database. In some embodiments, model selector 314 may identify models for use in a production procedure, such as based on scaled parameters of an unseen model.

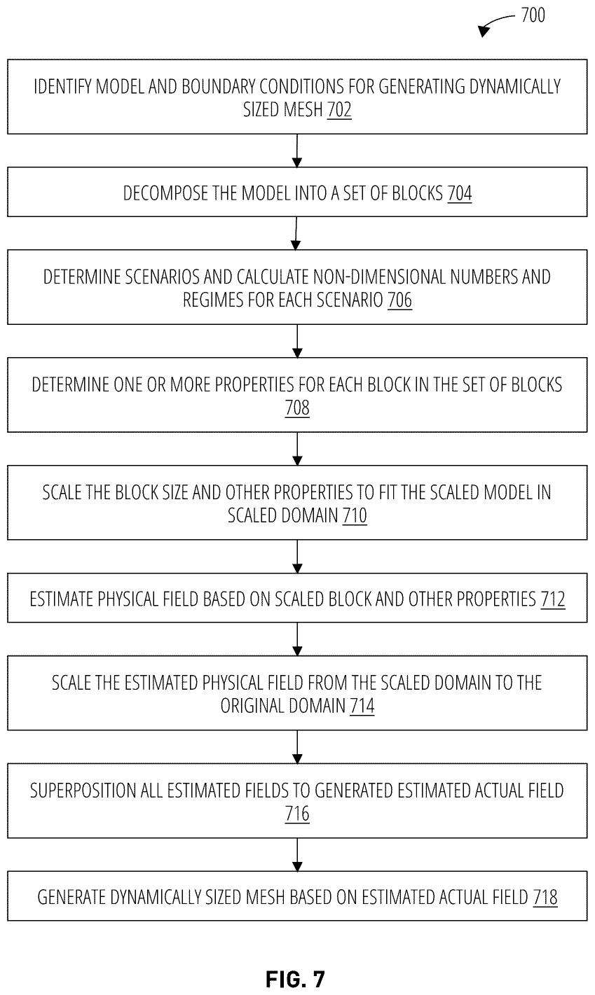

The production module 306 includes a decomposer 316, a parameterizer 318, a scaler 320, an estimator 322, a superpositioner 324, and a mesher 326. As described in more detail below, training module 304 may implement process flow 700 of FIG. 7 to generate a dynamically sized mesh for an unseen model. The decomposer 316 may decompose a model of an object into a set of blocks. The parameterizer 318 may determine one or more parameters for a model. For example, the parameterizer 318 may calculate or determine non-dimensional numbers, flow regime, and other properties of each block in the set of blocks. The scaler 320 may scale values between different domains. For example, scaler 320 may scale block parameters from the model domain (i.e., original or real domain) to the scaled domain (i.e., domain of the scaled model) and/or from the scaled domain to the model domain.

The estimator 322 may generate estimated physical fields for blocks. For example, estimator 322 may utilize one or more machine learning models in the trained model database of stored solutions to generate estimated physical fields. In one embodiments, the estimator 322 may provide data to the model selector 314 and, in response, the model selector 314 may provide the estimator 322 with a model to use. In other embodiments, the estimator 322 may incorporate the functionality of model selector 314. The superpositioner 324 may overlay all estimated fields for all blocks to predict the estimated solution of the entire computational domain for the unseen case (i.e., the estimated actual solution). The mesher 326 may generate a dynamically sized mesh based on the estimated actual solution. In some embodiments, the mesher 326 may calculate gradients, determine a size function based on the gradients, and utilize the size function to guide meshing.

FIG. 4 illustrates a process flow 400 of a training procedure for estimation of physical fields according to some embodiments. While process flow 400 is focused on a computational fluid dynamics/thermal problem, it will be appreciated that the techniques disclosed hereby can be applied to any physics or applications and the scaled model can be designed to accommodate the associated physics (e.g., electromagnetism, thermodynamics, acoustics, mechanics, optics, etc.). The process flow 400 is performed by processing logic that may comprise hardware (circuitry, dedicated logic, etc.), software (such as is run on a general purpose computer system or a dedicated machine), firmware, or a combination. In various embodiments, the process flow 400 is performed by one or more of one or more components of computing device 116, smart meshing platform 302, training module 304, computer-implemented environment 1400, system 1500a, system 1500b, and/or standalone computer architecture 1500c. Embodiments are not limited in this context.

Referring to FIG. 4, the process flow 400 begins at block 402. At block 402, a scaled model may be selected and configured. For example, the scaled model may be selected as a cube with the size of one meter in each direction, thermal conductivity of one watt per meter Kelvin, surface emissivity of 0, power density of 1 watt per cubic meter, and an ambient temperature of zero degree Celsius for training. Further the computational domain may be selected to be 10 times the size of the cube in the planar direction (i.e., 10 meters) and 25 times the size of the block in the flow direction (i.e., 25 meters). In some embodiments, simulator 308 may implement block 402.

At block 404, non-dimensional quantities may be determined for simulations and training of the scaled model. A certain number of non-dimensional quantities may be selected for simulations and training of the scaled model. For example, 11 Reynolds numbers (e.g., 1, 10, 50, 100, 500, 1000, 5000, 10000, 50000, 100000, 1000000) and 11 Rayleigh numbers (e.g., 1e3, 1e4, 1e5, 1e6, 1e7, 1e9, 1e11, 1e12, 1e13) can be selected for training. In various embodiments, any selected number of non-dimensional numbers to cover the associated physics can be picked. The exemplary Reynolds and Rayleigh numbers are selected to cover all flow regimes (i.e., laminar, mixed, turbulent). Additionally, in many embodiments, the number of non-dimensional quantities and/or values are selected to reduce the error in the accuracy of predictions (e.g., more numbers, more accurate). In various embodiments, simulator 308 may implemented block 404. Continuing to block 406, simulations may be performed on the scaled model using numerical techniques. For example, for various flow regimes (e.g., laminar, transition, and turbulent), the forced and natural convection flows around the block may be simulated using numerical techniques (e.g., finite volume method). In some embodiments, simulator 308 may implement block 406.

At block 408, variables and field data may be stored for each simulation. For example, variables and field data for the entire computational domain may be stored and used for each simulation. In various embodiments, simulator 308 may implemented block 408. Proceeding to block 410, models may be trained to estimate physical fields based on non-dimensional quantities. For example, the stored field data (i.e., solutions) from the simulations for each non-dimensional number may be fed to a linear regression algorithm. These trained models for each non-dimensional quantity (e.g., Reynolds or Rayleigh numbers) are the ones to be used in the production procedure for estimating physical fields. In some embodiments, model trainer 310 may implement block 410. Further, these trained models may be stored in the trained model database of stored solutions, such as by model manager 312.

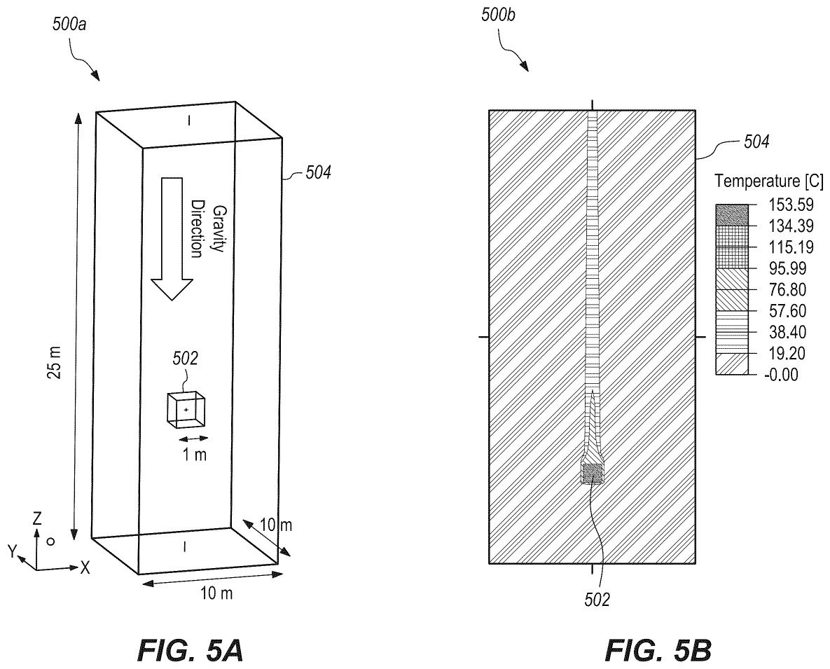

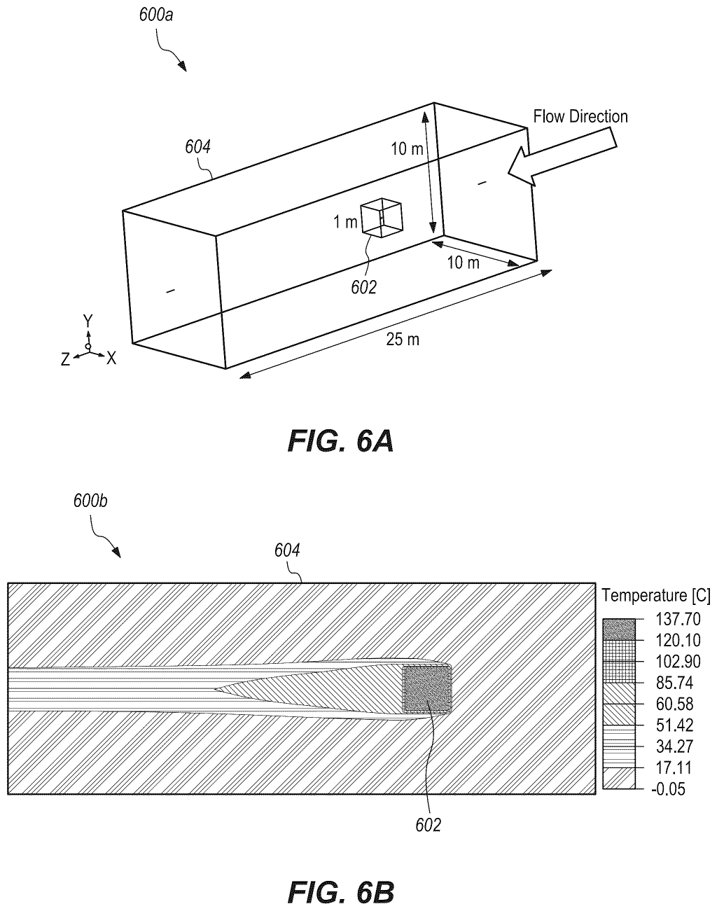

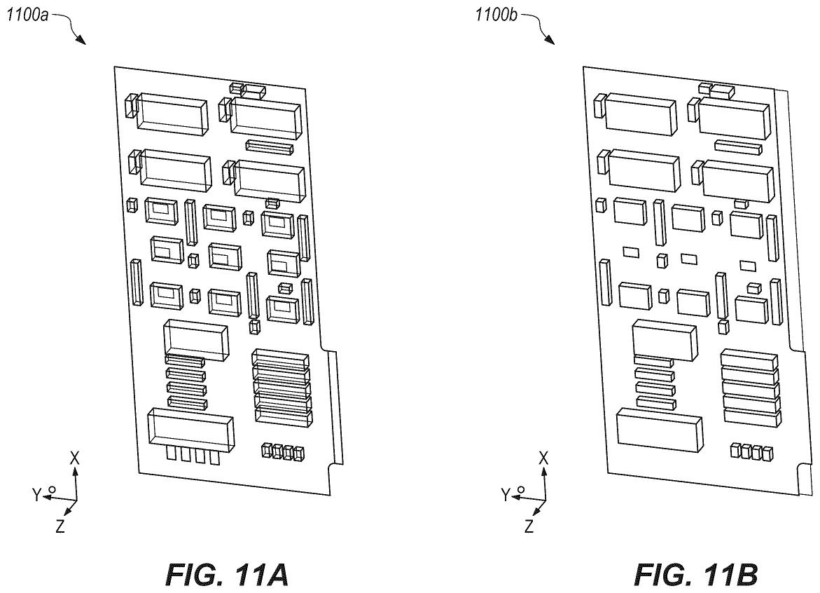

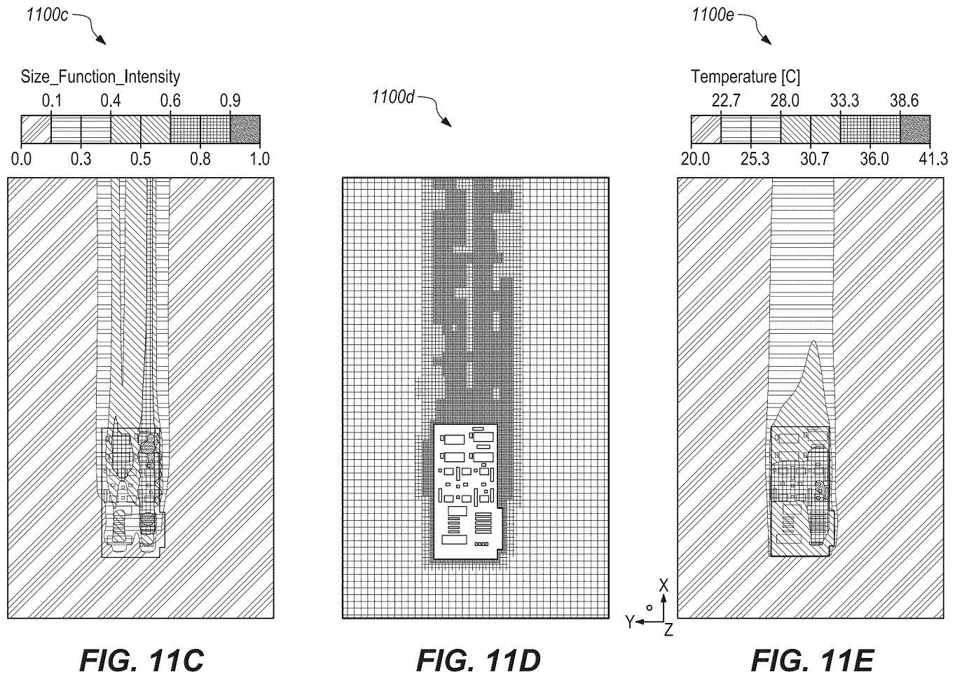

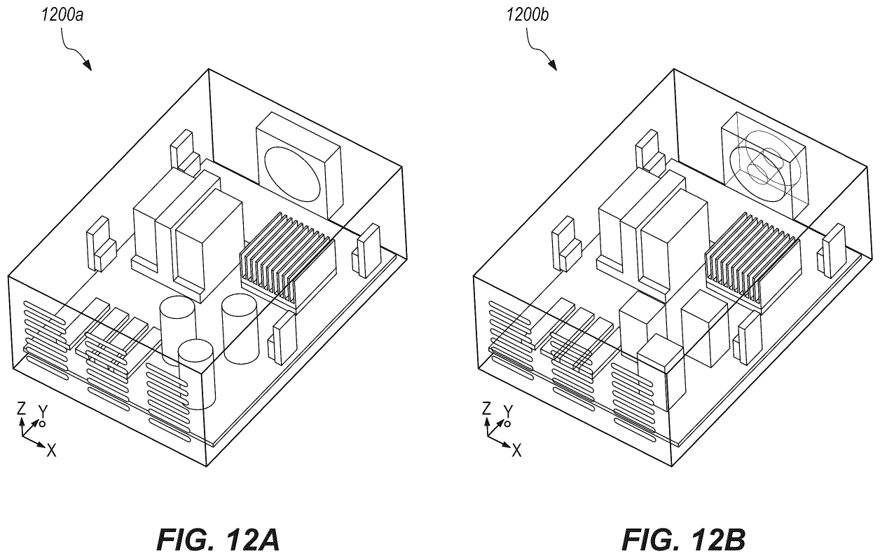

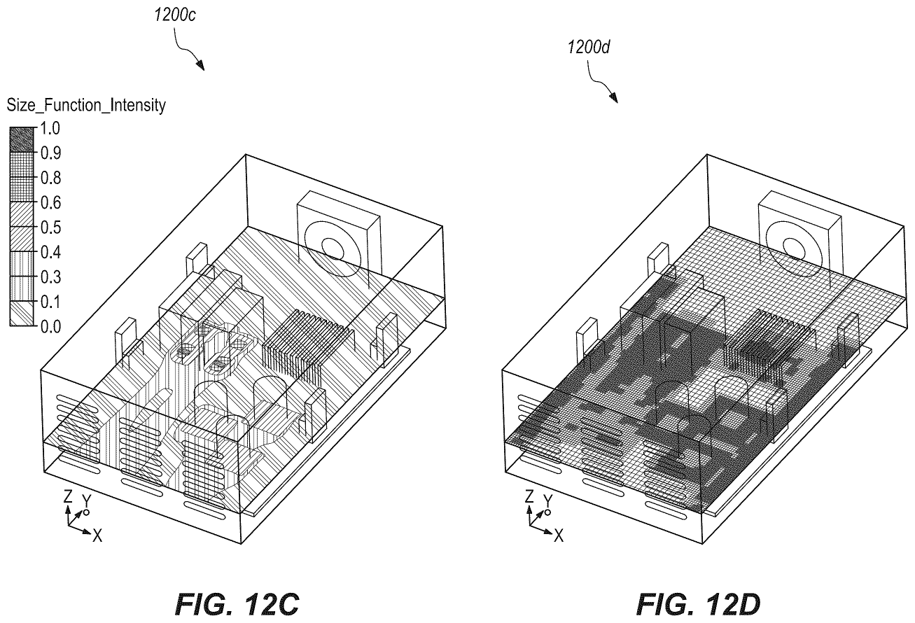

FIGS. 5A and 5B illustrate various aspects of a natural convection simulation utilized in a training procedure according to some embodiments. More specifically, FIG. 5A illustrates aspects of a simulation configuration 500a with scaled model 502 and computational domain 504 and FIG. 5B illustrates aspects of a simulated field 500b with scaled model 502 and computational domain 504. It will be appreciated that although the scale is illustrated with discrete values corresponding to specific hatchings, the scale may be continuous. For example, the scale may utilize blue for the coolest portions, red for the hottest portions, and a continuous transition between blue and red for the temperatures in between. This equally applies to other scales illustrated hereby without departing from the scope of this disclosure (see e.g., FIGS. 11C, 11E, and 12C). FIGS. 6A and 6B illustrate various aspects of a forced convection simulation utilized in a training procedure according to some embodiments. More specifically, FIG. 6A illustrates aspects of a simulation configuration 600a with scaled model 602 and computational domain 604 and FIG. 6B illustrates aspects of a simulated field 600b with scaled model 602 and computational domain 604.

In various embodiments, scaled external and internal flows with different flow regimes (laminar, transition, turbulent) may be simulated using computational fluid dynamics and finite volume methods. In the illustrated embodiments, a scaled model 502, 602 with the size of one meter in each direction, thermal conductivity of one watt per meter Kelvin, surface emissivity of 0, power density of 1 watt per cubic meter, and an ambient temperature of zero degree Celsius is selected. Further, the computational domain 504, 604 may be selected to be 10 times the size of the cube in the planar direction (i.e., 10 meters) and 25 times the size of the block in the flow direction (i.e., 25 meters). The Reynolds and Rayleigh numbers may be varied to cover a wide range of flow regimes. Temperature, flow velocities, or any other variable can be stored for training. Zero coordinates may be located at the block center.

FIG. 7 illustrates a process flow 700 for generating a dynamically sized mesh according to some embodiments. While process flow 700 is focused on a computational fluid dynamics/thermal problem, it will be appreciated that the techniques disclosed hereby can be applied to any physics or applications and the scaled model can be designed to accommodate the associated physics (e.g., electromagnetism, thermodynamics, acoustics, mechanics, optics, etc.). The process flow 700 is performed by processing logic that may comprise hardware (circuitry, dedicated logic, etc.), software (such as is run on a general purpose computer system or a dedicated machine), firmware, or a combination. In various embodiments, the process flow 700 is performed by one or more of one or more components of computing device 116, smart meshing platform 302, production module 306, computer-implemented environment 1400, system 1500a, system 1500b, and/or standalone computer architecture 1500c. Embodiments are not limited in this context.

Referring to FIG. 7, the process flow 700 begins at block 702. At block 702, a model and boundary conditions for generation a dynamically sized mesh may be identified. For example, a model of an object in an original domain with a set of boundary conditions may be received by a memory of a system. Any model with any complexity in geometries and/or physics (e.g., flow regime or natural or forced convection) can be selected for meshing. In some embodiments, block 702 of process flow 700 may be performed by parameterizer 318.

Continuing to block 704, the model may be decomposed into a set of blocks. For example, decomposer 316 may decompose the model into a set of blocks. In various embodiments, during decomposition, all solid zones in the model may be decomposed into blocks. In some embodiments, block 704 of process flow 700 may be performed by decomposer 316. In various embodiments, each of the blocks may have a threshold aspect ratio. For example, each block may have an aspect ratio at or above 0.8. In some embodiments, the blocks may be cubic or rectangular. Thus, the solid zones of the original domain for any unseen model is decomposed into a set of blocks. Further, each model may be re-constructed using the set of blocks. Each block may have a given set of properties for each physics (e.g., power density, material properties, surface emissivity, size, location, etc.). One or more of these properties may be provided with the model.

At block 706, scenarios may be determined and non-dimensional numbers and regimes may be calculated for each scenario. For example, based on the defined boundary conditions (e.g., ambient temperature, velocities, power, material assignments, etc.) in the model, the problem can be categorized (e.g., forced convection or natural convection, flow regime). In some embodiments, block 706 of process flow 700 may be performed by parameterizer 318. Non-dimensional number and subsequently flow regimes for each scenario can be calculated (e.g., Reynolds for forced convection and Rayleigh for natural convection). In the unseen model, flow regime and non-dimensional numbers may be calculated based on model boundary conditions and prior to meshing and solve. Proceeding to block 708, one or more properties for each block in the set of blocks can be determined. For example, each block in the decomposed model may have one or more given or determined properties (e.g., solid thermal conductivity, surface emissivity, power density, size, center location). In some embodiments, block 708 of process flow 700 may be performed by parameterizer 318.

At block 710, the block size and other properties may be scaled to fit the scaled model in the scaled domain. For example, block size and other properties may be scaled to fit to the trained scaled model using Buckingham x theorem for prediction purposes. Power density, material properties of solids (e.g., thermal conductivity), surface properties (e.g., emissivity) of each block are scaled with reference to the block size. In some embodiments, block 710 of process flow 700 may be performed by scaler 320. The scaling factors (e.g., for power, conductivity, emissivity) may be used to calculate the field using multi-level interpolations. The radiation portion of heat dissipation may be scaled with surface emissivity of the block in unseen cases as the worst case was utilized for training (i.e., emissivity of zero).

Proceeding to block 712, the physical field for each block may be estimated based on scaled block and other properties. For example, based on the calculated non-dimensional number for the unseen case and other scaled properties, the predicted solution for the variables of interest (e.g., temperature) can be calculated using the trained model database of stored solutions. In some embodiments, block 712 of process flow 700 may be performed by estimator 322. This may be done by multi-variable linear regression techniques or multi-level interpolations. Thus, based on the trained model database for given non-dimensional numbers, the field can be predicted by interpolating between the two closes fields in the trained set of models. In other words, non-dimensional numbers are used to call the trained models and to calculate field values. Then, other properties are used for multi-level scaling of the predicted field.

Continuing to block 714, the estimated physical field is scaled from the scaled domain to the original domain. For example, after prediction in the scaled domain, the field may be scaled back to the original domain knowing the block size and its center location in the computational domain. In some embodiments, block 714 of process flow 700 may be performed by scaler 320. Center location of blocks in the unseen model are known and the predicted field is rotated (e.g., based on the flow direction in unseen case versus the trained model) and moved (e.g., from zero coordinate in scaled model) to sit at the correct location. This prediction process may be done for every block in the model after decomposition. Further, ambient temperature in the unseen case can be added to the predicted field.

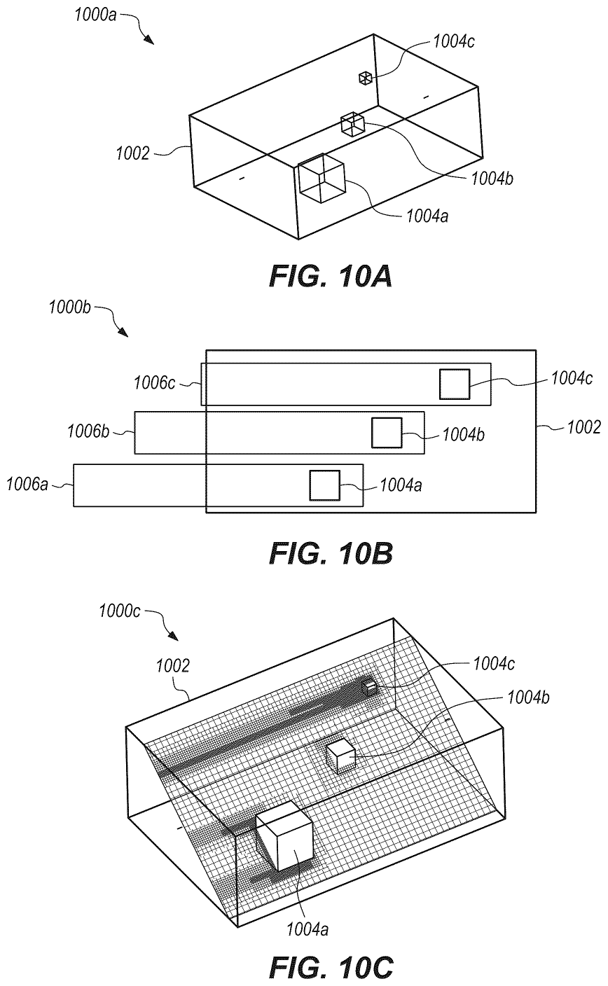

At block 716, all estimated fields are superpositioned to generate an estimated actual field for the unseen model. For example, after all predictions are completed, a superposition of all estimated fields is done to predict the estimated solution of the entire computational domain for the unseen case (i.e., estimated actual field). In other words, all predicted and scaled fields (scaled back to the original domain) are super-imposed and overlapping portions summed to predict the estimated actual field. In some embodiments, block 716 of process flow 700 may be performed by superpositioner 324. Aspects of superposition are described in more detail below, such as with respect to FIGS. 10A-10C.

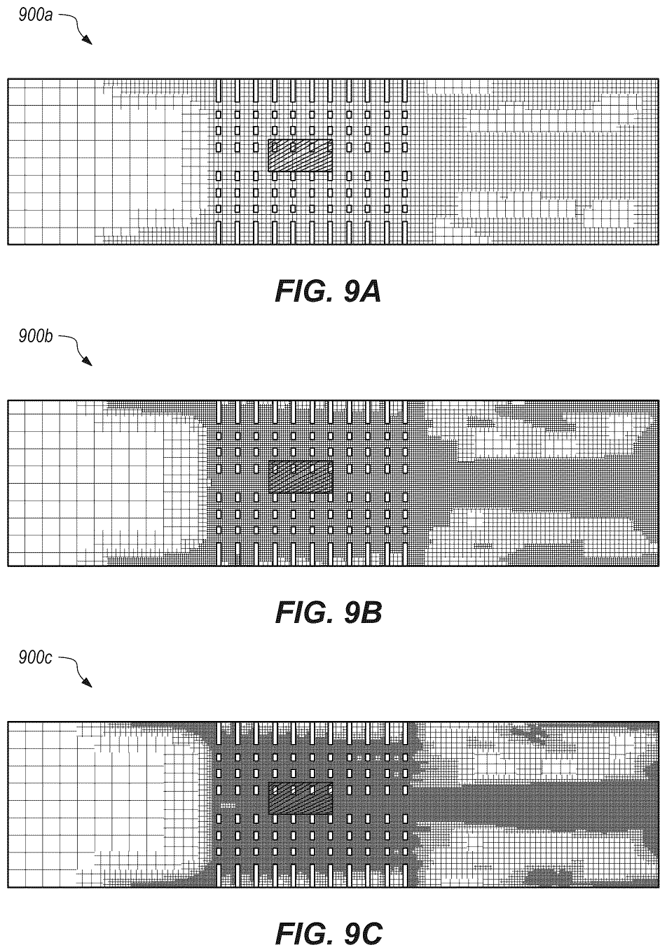

Proceeding to block 718, a dynamically sized mesh is generated based on the estimated actual field. For example, for each variable of interest (e.g., temperature), gradients may be calculated based on the estimated actual solution. Size functions may be calculated for meshing, and meshing is guided using the size function. In some embodiments, block 718 of process flow 700 may be performed by mesher 326. Aspects of generating a dynamically sized mesh are described in more detail below, such as with respect to FIGS. 9A-9C.

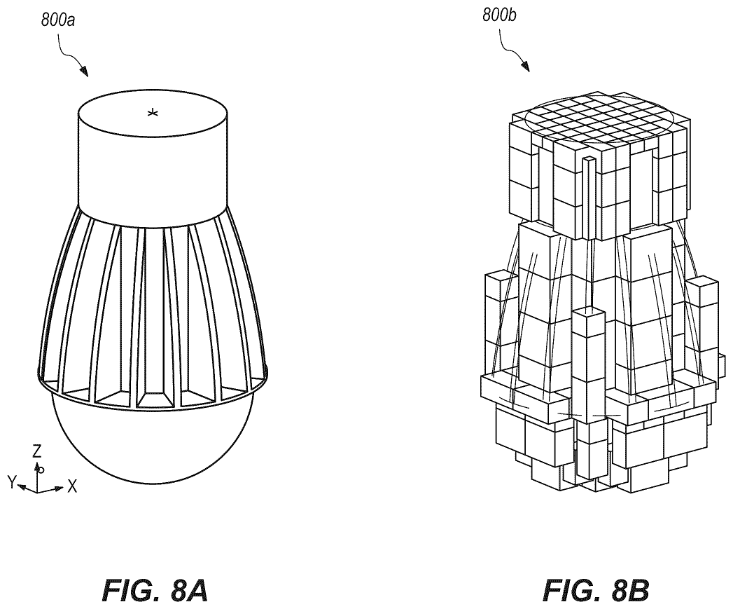

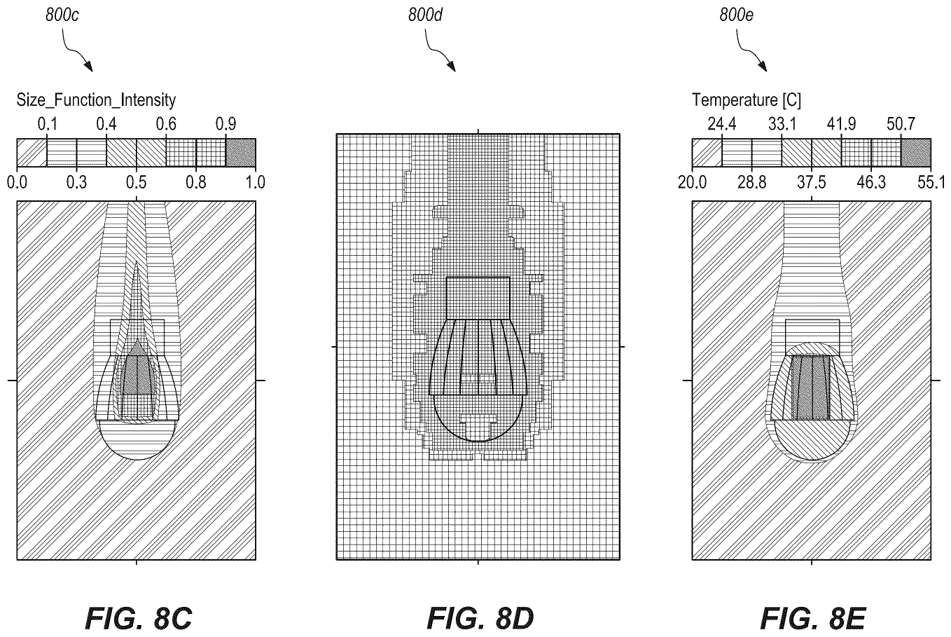

FIGS. 8A-8E illustrate various aspects of generating a dynamically sized mesh for a model of a light bulb according to some embodiments. More specifically, FIG. 8A illustrates an original model 800a, FIG. 8B illustrates a decomposed model 800b, FIG. 8C illustrates an estimated field 800c, FIG. 8D illustrates a dynamically sized mesh 800d, and FIG. 8E illustrates a full solution 800e. The illustrated embodiments are based on natural convection at an ambient temperature of 20 degrees Celsius and gravity is the −Z direction. Further, the total heat dissipation is 7 watts and the Rayleigh number is 1.15e7. As shown in FIGS. 8C and 8E, the estimated field 800c provides a sufficiently accurate estimation of the full solution 800e, which is produced by the solver stage (see e.g., block 106) after generation of the dynamically sized mesh. The estimated field 800c is used to guide the meshing. The method knows the flow direction and quickly calculates the estimated solution close to reality. The estimated solution does not have to be completely accurate because gradients are what matters most for meshing. As shown in FIG. 8C, the estimated field 800c includes a mesh pattern based on the physical fields (e.g., plume formation and flow from heat generated by the light bulb). Embodiments are not limited in this context.

FIGS. 9A-9C illustrate exemplary dynamically sized meshes generated based on different configurations according to some embodiments. More specifically, FIG. 9A illustrates a first mesh 900a, FIG. 9B illustrates a second mesh 900b, and FIG. 9C illustrates a third mesh 900c. The illustrated embodiments may correspond to trained model predictions used to estimate temperature field for an unseen speed of 0.43 meters per second. The different meshes may represent different configurations of the meshing procedure. For example, a slider bar setting may be utilized to determine the refinement level, up to the smallest size in distribution. Accordingly, the first mesh 900a may correspond to a configuration that utilizes a relatively large smallest size in distribution, the second mesh 900b may correspond to a configuration that utilizes a relatively medium smallest size in distribution, and the third mesh 900c may correspond to a configuration that utilizes a relatively small smallest size in distribution. Embodiments are not limited in this context.

More generally, the size distribution may be computed using the following exemplary size function shown in Equation 1, below.

$${l}_{p} = \frac{{LT}_{T}}{{T}_{max} - {T}_{min}} . \qquad Equation 1$$

In equation 1, the target size is lₚ, the current cell size is L, the target difference of temperature in the cell is T_{T}, the maximum temperature in the cell is Tₘₐₓ, and the minimum temperature in the cell is Tₘᵢₙ. In the illustrated embodiment, the mesh is generated with T_{T} set to 1 degree Celsius and the initial cell size is eight times larger than the training mesh.

In various embodiments, meshing may utilize the following procedure. First, all shapes are tessellated and features extracted. Second, the initial cartesian mesh may be refined based on the size functions and user-defined levels/size regions (e.g., slider position). In many embodiments, the size function may automate this aspect of meshing. Third, the mesh nodes may be projected to facets and features. Fourth, cells are decomposed using appropriate template based on how cells are intersected. Fifth, the decomposed cells are ray-traced to each shape and the shape boundary faces are extracted. Sixth, node smoothing, face swapping, and local-remeshing is performed to improve cell quality.

FIGS. 10A-10C illustrate various aspects of superpositioning according to some embodiments. More specifically, FIG. 10A illustrates a model 1000a with three blocks 1004a, 1004b, 1004c of different sizes and powers, FIG. 10B illustrates superpositioned field estimations 1000b including blocks 1004a, 1004b, 1004c and corresponding estimated field domains 1006a, 1006b, 1006c utilized to generate unknown scenarios from known configurations, and FIG. 10C illustrates a dynamically sized mesh 1000c from superposition-solution generated point size distribution including blocks 1004a, 1004b, 1004c. In various embodiments, superpositioning may overlay all estimated fields for all blocks to predict the estimated solution of the entire computational domain for an unseen case. Superpositioning is a practical solution to predict the entire field based on individual predictions and provides a mechanism to construct unseen scenarios from known configurations. The objective of the workflow is to predict an estimate and linear superposition may introduce some errors, but the errors do not prevent efficient generation of a dynamically sized mesh of sufficient accuracy. Embodiments are not limited in this context.

FIGS. 11A-11E illustrate various aspects of generating a dynamically sized mesh for a model of a printed circuit board and integrated circuit components according to some embodiments. More specifically, FIG. 11A illustrates an original model 1100a, FIG. 11B illustrates a decomposed model 1100b, FIG. 11C illustrates an estimated field 1100c, FIG. 11D illustrates a dynamically sized mesh 1100d, and FIG. 11E illustrates a full solution 1100e. The illustrated embodiments are based on natural convection at an ambient temperature of 20 degrees Celsius and gravity is the −X direction. Further, the total heat dissipation is 3 Watts and the Rayleigh number is 9.23e7. As shown in FIGS. 11C and 11E, the estimated field 1100c provides a sufficiently accurate estimation of the full solution 1100e, which is produced by the solver stage (see e.g., block 106) after generation of the dynamically sized mesh. The estimated field 1100c is used to guide the meshing. The method knows the flow direction and quickly calculates the estimated solution close to reality. The estimated solution does not have to be completely accurate because gradients are what matters most for meshing. Embodiments are not limited in this context.

FIGS. 12A-12D illustrate various aspects of generating a dynamically sized mesh for a model of an electronics enclosure box according to some embodiments. More specifically, FIG. 12A illustrates an original model 1200a, FIG. 12B illustrates a decomposed model 1200b, FIG. 12C illustrates an estimated field 1200c, and FIG. 12D illustrates a dynamically sized mesh 1200d. The illustrated embodiments are based on forced convection at an ambient temperature of 25 degrees Celsius and gravity is the −X direction. Further, the total heat dissipation is 3 Watts and the Rayleigh number is 9.23e7. As shown in FIGS. 11C and 11E, the estimated field 1100c provides a sufficiently accurate estimation. The estimated field 1100c is used to guide the meshing. The method knows the flow direction and quickly calculates the estimated solution close to reality. The estimated solution does not have to be completely accurate because gradients are what matters most for meshing. Embodiments are not limited in this context.

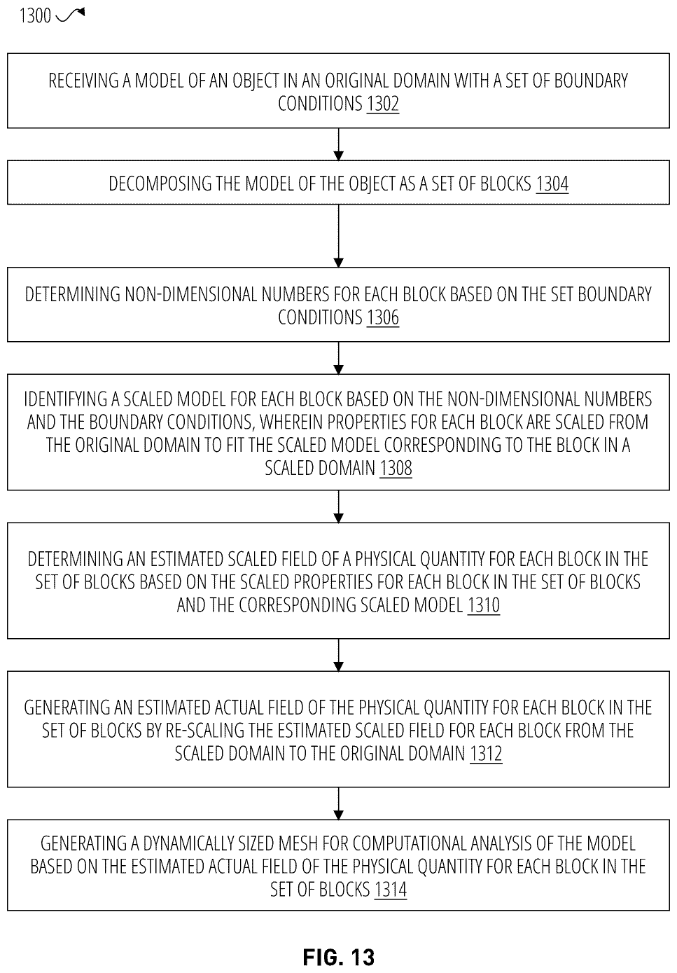

FIG. 13 illustrates a logic flow 1300 according to some embodiments. The logic flow 1300 is performed by processing logic that may comprise hardware (circuitry, dedicated logic, etc.), software (such as is run on a general purpose computer system or a dedicated machine), firmware, or a combination. In various embodiments, the logic flow 1300 is performed by one or more of one or more components of computing device 116, smart meshing platform 302, computer-implemented environment 1400, system 1500a, system 1500b, and/or standalone computer architecture 1500c. Embodiments are not limited in this context.

Referring to FIG. 13, the logic flow 1300 begins at block 1302. At block 1302, a model of an object in an original domain with a set of boundary conditions may be received. For example, original model 800a of a light bulb may be received with a set of boundary conditions. In some embodiments, the model may be received by a memory of a system, such as non-transitory computer-readable memory 1504, 1530 and/or data store 1506, 1522. Proceeding to block 1304, the model may be decomposed as a set of blocks. For example, decomposer 316 may decompose the original model 800a as a set of blocks in decomposed model 800b. In some embodiments, the model may be decomposed by one or more processors of a system, such as one or more processors in processing system 1502 or processing system 1520.

At block 1306 non-dimensional numbers may be determined for each block based on the set of boundary conditions. For example, parameterizer 318 may determine non-dimensional numbers for each block in decomposed model 800b. In some embodiments, the non-dimensional numbers may be determined by one or more processors of a system, such as one or more processors in processing system 1502 or processing system 1520. Continuing to block 1308, a scaled model for each block may be identified based on the non-dimensional numbers and the boundary conditions. Additionally, properties for each block may be scaled from the original domain to fit the scaled model corresponding to the block in a scaled domain. For example, model selector 314 may identify a scaled model for each block based on the non-dimensional numbers and the boundary conditions. Further, scaler 320 may scale properties for each block from the original domain to fit the scaled model corresponding to the block in a scaled domain. In some embodiments, the scaled model for each block may be identified by one or more processors of a system, such as one or more processors in processing system 1502 or processing system 1520.

Proceeding to block 1310, an estimated scaled field of a physical quantity for each block in the set of blocks may be determined based on the scaled properties for each block in the set of blocks and the corresponding scaled model. For example, the estimator 322 may determine an estimated scaled field for a physical quantity for each block in the set of blocks based on the scaled properties for each block in the set of blocks and the corresponding scaled model. In some embodiments, the estimated scaled field of a physical quantity for each block in the set of blocks may be determined by one or more processors of a system, such as one or more processors in processing system 1502 or processing system 1520. At block 1312 an estimated actual field of the physical quantity for each block in the set of blocks may be generated by re-scaling the estimated scaled field for each block from the scaled domain to the original domain. For example, scaler 320 may determine estimated field 800c as the estimated actual field by re-scaling the estimated scaled field for each block from the scaled domain to the original domain. In some embodiments, the estimated actual field may be determined by one or more processors of a system, such as one or more processors in processing system 1502 or processing system 1520.

Continuing to block 1314, a dynamically sized mesh for computational analysis of the model may be generated based on the estimated actual field of the physical quantity for each block in the set of blocks. For example, mesher 326 may generate dynamically sized mesh 800d for computational analysis of the original model 800a may be generated based on the estimated actual field of the physical quantity for each block in the set of blocks. In some embodiments, the dynamically sized mesh may be generated by one or more processors of a system, such as one or more processors in processing system 1502 or processing system 1520.

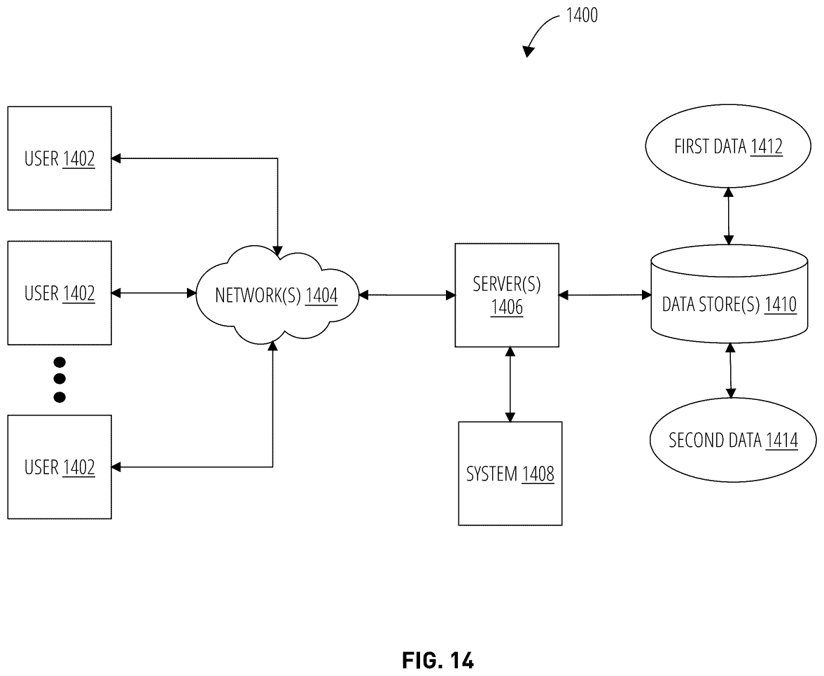

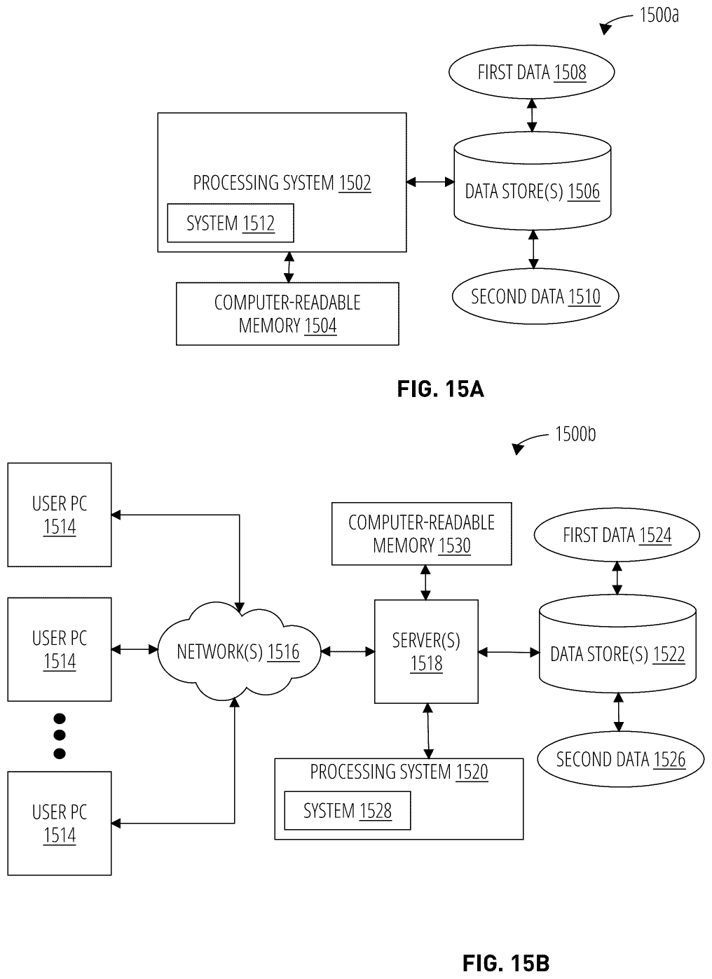

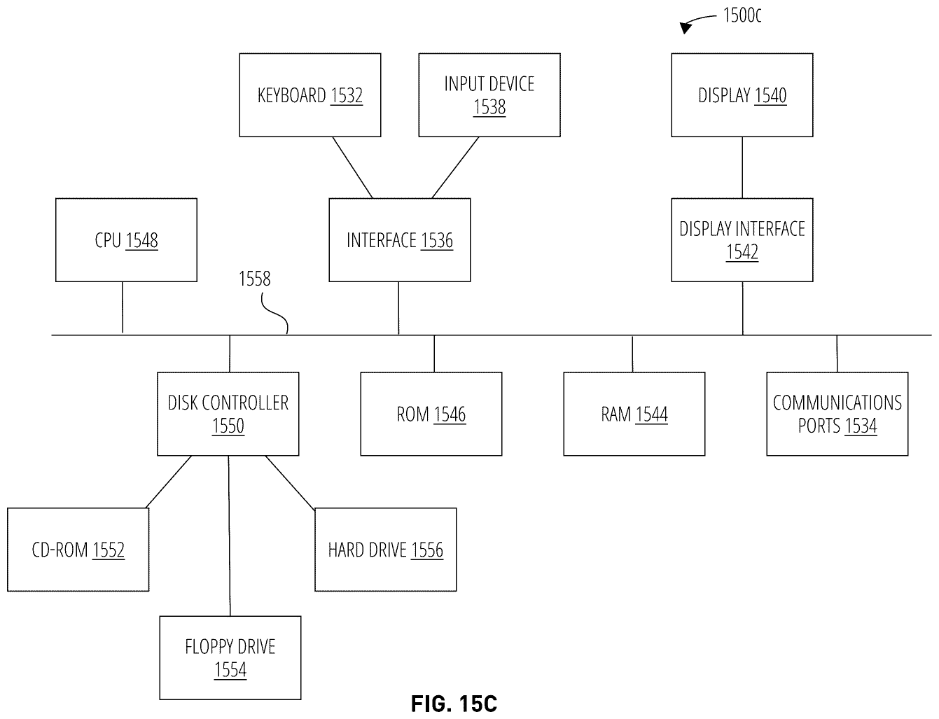

The methods and systems described herein may be implemented using any suitable processing system with any suitable combination of hardware, software, and/or firmware, such as described below with reference to the non-limiting examples of FIG. 14, FIG. 15A, FIG. 15B, and FIG. 15C.

FIG. 14 depicts a computer-implemented environment 1400 wherein users 1402 can interact with a system 1408 hosted on one or more server(s) 1406 through one or more network(s) 1404. The one or more server(s) 1406 are coupled to one or more data store(s) 1410. In some embodiments, the one or more data store(s) 1410 are coupled to the one or more server(s) 1406 via the one or more network(s) 1404. The data store(s) 1410 can store data utilized by the system 1408, such as first data 1412 and second data 1414 The system 1408 contains software operations or routines. The users 1402 can interact with the system 1408 through a number of ways, such as over one or more network(s) 1404. One or more server(s) 1406 accessible through the network(s) 1404 can host system 1408. It should be understood that the system 1408 could also be provided on a stand-alone computer for access by a user.

FIGS. 15A-15C depict example systems for use in implementing a system. For example, FIG. 15A depicts an exemplary system 1500a that includes a standalone computer architecture where a processing system 1502 (e.g., one or more computer processors located in a given computer or in multiple computers that may be separate and distinct from one another) includes a system 1512 (e.g., one or more of smart meshing platform 302, training module 304, and production module 306) being executed on it. The processing system 1502 has access to a non-transitory computer-readable memory 1504 in addition to one or more data store(s) 1506. The one or more data store(s) 1506 may contain first data 1508 (e.g., an unseen model) as well as second data 1510 (e.g., a trained model database of stored solutions). The processing system 1502 may be a distributed parallel computing environment, which may be used to handle very large scale data sets.

FIG. 15B depicts a system 1500b that includes a client server architecture. One or more user PCs 1514 access one or more server(s) 1518 running a system 1528 (e.g., one or more of smart meshing platform 302, training module 304, and production module 306) on a processing system 1520 via one or more network(s) 1516. The one or more server(s) 1518 may access a non-transitory computer-readable memory 1530 as well as one or more data store(s) 1522. The one or more data store(s) 1522 may contain first data 1524 (e.g., an unseen model) as well as second data 1526 (e.g., a trained model database of stored solutions).

FIG. 15C shows a block diagram of exemplary hardware for a standalone computer architecture 1500c, such as the architecture depicted in FIG. 15A, that may be used to contain and/or implement the program instructions of system embodiments of the present disclosure. A system bus 1558 may serve as the information highway interconnecting the other illustrated components of the hardware. A processing system 1548 labeled CPU (central processing unit) (e.g., one or more computer processors), may perform calculations and logic operations required to execute a program. A non-transitory computer-readable storage medium, such as read only memory (ROM) 1546 and random access memory (RAM) 1544, may be in communication with the CPU 1548 and may contain one or more programming instructions. Optionally, program instructions may be stored on a non-transitory computer-readable storage medium such as a magnetic disk, optical disk, recordable memory device, flash memory, or other physical storage medium. Computer instructions may also be communicated via a communications signal, or a modulated carrier wave, e.g., such that the instructions may then be stored on a non-transitory computer-readable storage medium.

A disk controller 1550 interfaces one or more optional disk drives to the system bus 1558 These disk drives may be external or internal floppy disk drives such as floppy drive 1554, external or internal CD-ROM, CD-R, CD-RW, or DVD drives such as 1552. As indicated previously, these various disk drives and disk controllers are optional devices. One or more of the components described hereby may include a software application stored in one or more of the disk drives connected to the disk controller 1550, the ROM 1546, and/or the RAM 1544. In various embodiments, the CPU 1548 may access each component as required.

A display interface 1542 may permit information from the system bus 1558 to be displayed on a display 1540 in audio, graphic, or alphanumeric format. Communication with external devices may optionally occur using various communications ports 1534.

The hardware may also include data input devices, such as keyboard 1532 and one or more other input devices 1538, such as a microphone, remote control, pointer, mouse, touchscreen, and/or joystick.

This written description describes exemplary embodiments, but other variations fall within scope of the disclosure. For example, the systems and methods may include and utilize data signals conveyed via networks (e.g., local area network, wide area network, internet, combinations thereof, etcetera), fiber optic medium, carrier waves, wireless networks, etcetera for communication with one or more data processing devices. The data signals can carry any or all of the data disclosed herein that is provided to or from a device.

The methods and systems described herein may be implemented on many different types of processing devices by program code comprising program instructions that are executable by the device processing system. The software program instructions may include source code, object code, machine code, or any other stored data that is operable to cause a processing system to perform the methods and operations described herein. Any suitable computer languages may be used such as C, C++, Java, etcetera, as will be appreciated by those skilled in the art. Other implementations may also be used, however, such as firmware or even appropriately designed hardware configured to carry out the methods and systems described herein.

The systems' and methods' data (e.g., associations, mappings, data input, data output, intermediate data results, final data results, etcetera) may be stored and implemented in one or more different types of computer-implemented data stores, such as different types of storage devices and programming constructs (e.g., RAM, ROM, flash memory, flat files, databases, programming data structures, programming variables, IF-THEN (or similar type) statement constructs, etcetera). It is noted that data structures describe formats for use in organizing and storing data in databases, programs, memory, or other non-transitory computer-readable media for use by a computer program.

The computer components, software modules, functions, data stores, and data structures described herein may be connected directly or indirectly to each other in order to allow the flow of data needed for their operations. It is also noted that a module or processor includes but is not limited to a unit of code that performs a software operation, and can be implemented for example as a subroutine unit of code, or as a software function unit of code, or as an object (as in an object-oriented paradigm), or as an applet, or in a computer script language, or as another type of computer code. The software components and/or functionality may be located on a single computer or distributed across multiple computers depending upon the situation at hand.

One or more aspects or features of the subject matter described herein can be realized in digital electronic circuitry, integrated circuitry, specially designed application specific integrated circuits (ASICs), field programmable gate arrays (FPGAs), computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system may include clients and servers. A client and server are generally remote from each other and typically interact through a communication network. The relationship of client and server arises by virtue of computer programs running on the respective computers and having a client-server relationship to each other.

These computer programs, which can also be referred to as programs, software, software applications, components, or code, include machine instructions for a programmable processor, and can be implemented in a high-level procedural language, an object-oriented programming language, a functional programming language, a logical programming language, and/or in assembly/machine language. As used herein, the term “machine-readable medium” refers to any computer program product, apparatus, and/or device, such as for example magnetic disks, optical disks, memory, and Programmable Logic Devices (PLDs), used to provide machine instructions and/or data to a programmable processor, including a machine-readable medium that receives machine instructions as a machine-readable signal. The term “machine-readable signal” refers to any signal used to provide machine instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example as would a processor cache or other random access memory associated with one or more physical processor cores.

In the descriptions above and in the claims, phrases such as “at least one of” or “one or more of” may occur followed by a conjunctive list of elements or features. Unless otherwise implicitly or explicitly contradicted by the context in which it is used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C”;““one or more of A, B, and C;” and “A, B, and/or C” are each intended to mean “A alone, B alone, C alone, A and B together, A and C together, B and C together, or A and B and C together.” In addition, use of the term “based on,” above and in the claims is intended to mean, “based at least in part on,” such that an unrecited feature or element is also permissible.

The subject matter described herein can be embodied in systems, apparatus, methods, and/or articles depending on the desired configuration. The implementations set forth in the foregoing description do not represent all implementations consistent with the subject matter described hereby. Instead, they are merely some examples consistent with aspects related to the described subject matter. Although a few variations have been described in detail above, other modifications and/or additions are possible. In particular, further features and/or variations can be provided in addition to those set forth herein. For example, the implementations described above can be directed to various combinations and subcombinations of the disclosed features and/or combinations and subcombinations of several further features disclosed hereby. In addition, the logic flows depicted in the accompanying figures and/or described herein do not necessarily require the particular order shown, or sequential order, to achieve desirable results. Other implementations may be within the scope of the following claims.

It should be understood that as used in the description herein and throughout the claims that follow, the meaning of “a,” “an,” and “the” includes plural reference unless the context clearly dictates otherwise. Also, as used in the description herein and through out the claims that follow, the meaning of “in” includes “in” and “on” unless the context clearly dictates otherwise. Finally, as used in the description herein and throughout the claims that follow, the meanings of “and” and “or” include bother the conjunctive and disjunctive and may be used interchangeably unless the context expressly dictates otherwise; the phrase “exclusive or” may be used to indicate situation where only the disjunctive meaning may apply.

The preceding detailed descriptions are presented in terms of algorithms and symbolic representations of operations on data bits within a device memory. These algorithmic descriptions and representations are the tools used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be kept in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “receiving,” “determining,” “sending,” “terminating,” “waiting,” “changing,” or the like, refer to the action and processes of a device, or similar electronic computing device, that manipulates and transforms data represented as physical (electronic) quantities within the device's registers and memories into other data similarly represented as physical quantities within the device memories or registers or other such information storage, transmission, or display de vices.

The processes and displays presented herein are not inherently related to any particular device or other apparatus. Various general-purpose systems may be used with programs in accordance with the teachings herein, or it may prove convenient to construct a more specialized apparatus to perform the operations described. The required structure for a variety of these systems will be evident from the description. In addition, the disclosure is not described with reference to any particular programming language. It will be appreciated that a variety of programming languages may be used to implement the teachings of the disclosure as described hereby.

In the foregoing specification, specific exemplary embodiments have been described. It will be evident that various modifications may be made to those embodiments without departing from the broader spirit and scope set forth in the following claims. The specification and drawings are, accordingly, to be regarded in an illustrative sense rather than a restrictive sense.

What is claimed is:

1. A computer-implemented method, comprising:
receiving, by a memory of a system, a model of an object in an original domain with a set of boundary conditions;
decomposing, by one or more processors of the system, the model of the object as a set of blocks;
determining, by the one or more processors of the system, non-dimensional numbers for each block based on the set of boundary conditions;
identifying a scaled model for each block based on the non-dimensional numbers and the boundary conditions, wherein properties for each block are scaled from the original domain to fit the scaled model corresponding to the block in a scaled domain;
determining, by the one or more processors of the system, an estimated scaled field of a physical quantity for each block in the set of blocks based on the scaled properties for each block in the set of blocks and the corresponding scaled model;
generating an estimated actual field of the physical quantity for each block in the set of blocks by re-scaling the estimated scaled field for each block from the scaled domain to the original domain; and
generating, by the one or more processors of the system, a dynamically sized mesh for computational analysis of the model based on the estimated actual field of the physical quantity for each block in the set of blocks.

2. The computer-implemented method of claim 1, wherein the non-dimensional numbers comprise at least one of a Reynolds number and a Rayleigh number.

3. The computer-implemented method of claim 1, wherein determining, by the one or more processors of the system, the estimated scaled field of the physical quantity for each block in the set of blocks based on the set of scaled properties for each block in the set of blocks comprises performing a multi-variable linear regression or a multi-level interpolation using a trained model database of stored solutions of fields of the physical quantity for the scaled model in the scaled domain.

4. The computer-implemented method of claim 3, wherein the trained model database of stored solutions is generated based on solutions to simulations performed on the scaled model.

5. The computer-implemented method of claim 1, further comprising:
superpositioning the estimated actual field of the physical quantity for each block in the set of blocks onto the model; and
summing overlapping estimated actual fields to determine the estimated actual field of the physical quantity for the object.

6. The computer-implemented method of claim 5, further comprising:
calculating a set of gradient values based on the estimated final field of the physical quantity for the object and estimated fields for the set of blocks; and
generating, by the one or more processors of the system, the dynamically sized mesh for computational analysis of the model based on the set of gradient values.

7. The computer-implemented method of claim 5, comprising summing overlapping estimated actual fields and adding an ambient value of the physical quantity to determine the final estimated field of the physical quantity for the object.

8. The computer-implemented method of claim 7, wherein the physical quantity comprises temperature and the ambient value comprises an ambient temperature.

9. The computer-implemented method of claim 1, wherein each block in the set of blocks has a minimum aspect ratio of 0.8.

10. The computer-implemented method of claim 1, wherein the scaled model is a rectangular block.

11. An apparatus, comprising:
memory storing instructions; and
one or more processor coupled to the memory, the one or more processors executing the instructions from memory, the one or more processors configured to perform a method including:
receiving a model of an object in an original domain with a set of boundary conditions;
decomposing the model of the object as a set of blocks;
determining non-dimensional numbers for each block based on the set of boundary conditions;
identifying a scaled model for each block based on the non-dimensional numbers and the boundary conditions, wherein properties for each block are scaled from the original domain to fit the scaled model corresponding to the block in a scaled domain;
determining an estimated scaled field of a physical quantity for each block in the set of blocks based on the scaled properties for each block in the set of blocks and the corresponding scaled model;
generating an estimated actual field of the physical quantity for each block in the set of blocks by re-scaling the estimated scaled field for each block from the scaled domain to the original domain; and
generating a dynamically sized mesh for computational analysis of the model based on the estimated actual field of the physical quantity for each block in the set of blocks.

12. The apparatus of claim 11, wherein the non-dimensional numbers comprise at least one of a Reynolds number and a Rayleigh number.

13. The apparatus of claim 11, wherein determining the estimated scaled field of the physical quantity for each block in the set of blocks based on the set of scaled properties for each block in the set of blocks comprises performing a multi-variable linear regression or a multi-level interpolation using a trained model database of stored solutions of fields of the physical quantity for the scaled model in the scaled domain.

14. The apparatus of claim 13, wherein the trained model database of stored solutions is generated based on solutions to simulations performed on the scaled model.

15. The apparatus of claim 11, wherein the one or more processors are further configured to perform the method including:
superpositioning the estimated actual field of the physical quantity for each block in the set of blocks onto the model; and
summing overlapping estimated actual fields to determine the estimated actual field of the physical quantity for the object.

16. The apparatus of claim 15, wherein the one or more processors are further configured to perform the method including:
calculating a set of gradient values based on the estimated final field of the physical quantity for the object and estimated fields for the set of blocks; and
generating the dynamically sized mesh for computational analysis of the model based on the set of gradient values.

17. The apparatus of claim 15, wherein the one or more processors are further configured to perform the method including summing overlapping estimated actual fields and adding an ambient value of the physical quantity to determine the final estimated field of the physical quantity for the object.

18. At least one non-transitory machine-readable medium storing executable program instructions which when executed by a data processing system cause the data processing system to perform a method, the method comprising:
receiving a model of an object in an original domain with a set of boundary conditions;
decomposing the model of the object as a set of blocks;
determining non-dimensional numbers for each block based on the set of boundary conditions;
identifying a scaled model for each block based on the non-dimensional numbers and the boundary conditions, wherein properties for each block are scaled from the original domain to fit the scaled model corresponding to the block in a scaled domain;
determining an estimated scaled field of a physical quantity for each block in the set of blocks based on the scaled properties for each block in the set of blocks and the corresponding scaled model;
generating an estimated actual field of the physical quantity for each block in the set of blocks by re-scaling the estimated scaled field for each block from the scaled domain to the original domain; and
generating a dynamically sized mesh for computational analysis of the model based on the estimated actual field of the physical quantity for each block in the set of blocks.

19. The at least one non-transitory machine-readable medium of claim 18, wherein determining the estimated scaled field of the physical quantity for each block in the set of blocks based on the set of scaled properties for each block in the set of blocks comprises performing a multi-variable linear regression or a multi-level interpolation using a trained model database of stored solutions of fields of the physical quantity for the scaled model in the scaled domain.

20. The at least one non-transitory machine-readable medium of claim 18, further comprising instructions which when executed by the data processing system cause the data processing system to perform the method comprising:
superpositioning the estimated actual field of the physical quantity for each block in the set of blocks onto the model; and
summing overlapping estimated actual fields to determine the estimated actual field of the physical quantity for the object.
